(19) United States
(12) Patent Application Publication
(10) Pub. No.: US 2023/0232561 A1
(43) Pub. Date: Jul. 20, 2023

(54) METHOD AND SYSTEM FOR PROVIDING MULTIPLE SEALS FOR A COMPACT VACUUM CELL

(71) Applicant: ColdQuanta, Inc., Boulder, CO (US)

(72) Inventors: Clinton Cahall, Lafayette, CO (US); Jayson Denney, Golden, CO (US); Thomas William Noel, Lafayette, CO (US); Hugo Leon, Longmont, CO (US); Steffen Michael Kross, Boulder, CO (US); James S. Hale, Longmont, CO (US); Colin Fitzgerald, Boulder, CO (US); Matthew Barton Jaskot, Golden, CO (US)

(21) Appl. No.: 18/085,501

(22) Filed: Dec. 20, 2022

Related U.S. Application Data
(60) Provisional application No. 63/292,107, filed on Dec. 21, 2021.
(60) Provisional application No. 63/355,005, filed on Jun. 23, 2022.

(51) Int. Cl. H05K 5/06; G21K 1/00

(52) U.S. Cl. CPC H05K 5/066; G21K 1/00

(57) ABSTRACT

A vacuum cell including a vacuum chamber, a first bond, and a second bond is described. The first bond affixes a first portion of the vacuum cell to a second portion of the vacuum cell. The first bond has a first bonding temperature and a first debonding temperature greater than the first bonding temperature. The second bond affixes a third portion of the vacuum cell to a fourth portion of the vacuum cell. The second bond has a second bonding temperature and a second debonding temperature. The second bonding temperature is less than the first debonding temperature.

### CROSS REFERENCE TO OTHER APPLICATIONS

This application claims priority to U.S. Provisional Patent Application No. 63/292,107 entitled VACUUM SEALING OF A COMPACT VACUUM CELL CONTAINING AND ION TRAP OR RELATED COMPONENTS filed Dec. 21, 2021, and U.S. Provisional Patent Application No. 63/355,005 entitled COMPACT VACUUM CELL HAVING SEALED VIEWPORT ASSEMBLIES, CELL WALLS HAVING INTEGRATED PHOTONICS, AND PREFORMLESS BONDING PROCESSES USABLE IN VACUUM CELL PRODUCTION filed Jun. 23, 2022, both of which are incorporated herein by reference for all purposes.

### GOVERNMENT SUPPORT

This invention was made with support under contract FA8750-20-C-0548 awarded by AFRL/RIKF. The government has certain rights in the invention.

### BACKGROUND OF THE INVENTION

Vacuum cells may be capable of achieving a high vacuum (HV) or an ultra-high vacuum (UHV), e.g. pressures of 10⁻⁹ Torr or less, within interior vacuum chambers. These HV and UHV vacuum chambers may be utilized in a number of applications, such as applications those involving atomic vapor, cold atoms, and/or trapped ions. For example, such vacuum cells may be used in quantum computing, basic research, sensors, atomic clocks, and other in technologies.

In order to assemble vacuum cells capable of reaching and maintaining HV or UHV pressures in their vacuum chambers, the components of the vacuum cell are fabricated, affixed together, and sealed such that a hermetic seal may be formed in the vacuum chamber during use. Optical access to the vacuum chamber for lasers and viewports may also be provided. To do so, these portions of the vacuum cell are aligned with apertures in the walls and affixed, forming a hermetic seal. Components such as ion traps, integrated pumping cartridges and/or integrated atomic targets may also be desired to be present in the vacuum cell. Such components may be fabricated and attached to the vacuum cell during fabrication. Further, electrical feedthroughs, optical (e.g. fiber optic, photonic integrated circuits, etc.) feedthroughs, and/or ion pump attachments may also be integrated into the vacuum cell. The vacuum cell may also be desired to be baked out or otherwise treated to reduce outgassing of components and other issues that may adversely affect operation of the vacuum cell.

Although UHV vacuum cells can be fabricated, improvements are desired. For example, the assembly of vacuum cells including multiple components therein may be challenging. Silver epoxy or brazing may be used to attached components within the vacuum chamber, while an indium preform may be used to form a hermetic seal between a lid and the walls of the vacuum cell. However, the low melting point of indium (approximately 157 degrees Celsius) limits the use high temperature fabrication steps (e.g. bake outs) once the indium preform is in place. Moreover, the seal formed by the indium preform may be less robust than desired. Consequently, techniques for addressing challenges to fabricating and utilizing UHV vacuum cells are desired.

### BRIEF DESCRIPTION OF THE DRAWINGS

Various embodiments of the invention are disclosed in the following detailed description and the accompanying drawings.

FIGS. 1A-1B depict block diagrams of an embodiment of a vacuum cell including multiple bonds.

FIG. 2 depicts an embodiment of system for fabricating a vacuum cell.

FIGS. 3A-3C are diagrams depicting a perspective view of a portion of one embodiment of a vacuum cell including multiple bonds.

FIGS. 4A-4B are diagrams depicting a perspective view of a portion of embodiments of a vacuum cell including multiple bonds.

FIGS. 5A-5C are diagrams depicting a perspective view of a portion of an embodiment of a vacuum cell including multiple bonds.

FIG. 6 is a flow chart depicting an embodiment of a method for assembling a vacuum cell including multiple bonds.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

A vacuum cell including a vacuum chamber, a first bond, and a second bond is described. The first bond affixes a first portion of the vacuum cell to a second portion of the vacuum cell. The first bond has a first bonding temperature and a first debonding temperature greater than the first bonding temperature. The second bond affixes a third portion of the vacuum cell to a fourth portion of the vacuum cell. The second bond has a second bonding temperature and a second debonding temperature. The second bonding temperature is less than the first debonding temperature.

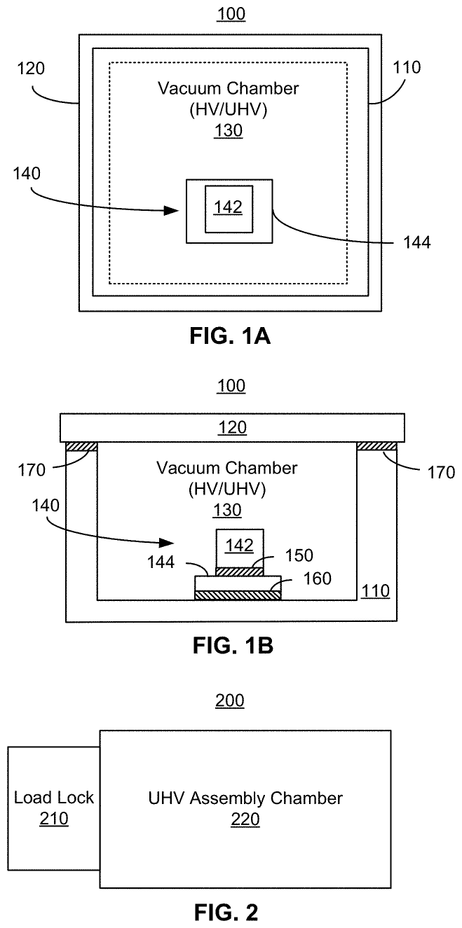

FIGS. 1A-1B depict block diagrams of an embodiment of vacuum cell 100 including multiple bonds 150, 160, and 170. FIG. 1A represents a top view, while FIG. 1B represents a cross-sectional side view of vacuum cell 100. For simplicity, bonds 150, 160, and 170 are shown only in FIG. 1B. Vacuum chamber 100 includes body 110 and lid 130, which define vacuum chamber 130 therein. For simplicity, vacuum cell 100 is depicted as having a simple, rectangular shape and a single vacuum chamber 130 therein. In some embodiments, vacuum cell 100 and/or vacuum chamber 130 may have different shapes. Further, although shown as including a single vacuum chamber 130, vacuum cell 100 may have multiple vacuum chambers, as well as other chambers, therein. Although not depicted in FIGS. 1A-1B, vacuum cell 100 may include view ports, other optical access (e.g. for laser light), other connections (e.g. electrical feed throughs and/or connections for an ion or other pump), and/or other features. Such additional features may complicate the shape of vacuum cell 100 and/or may require additional bonds.

In the embodiment shown, lid 120 is bonded to body 110 via bond 170. Bond 170 is between vacuum chamber 130 and the ambient environment outside of vacuum cell 100. For example, bond 170 may be between vacuum chamber 130 and room temperature/pressure in the location at which vacuum cell 100 is used. Thus, bond 170 is a hermetic bond capable of maintaining the pressure difference between vacuum chamber 120 and the ambient environment.

Vacuum chamber 130 may be a high vacuum (HV), ultra-high vacuum (UHV), or lower pressure (e.g. XHV) chamber. For example, vacuum chamber 130 may be capable of reaching and maintaining pressures on the order of not more than 10⁻³ Torr, or less (e.g. not more than 10⁻⁹ Torr, not more than 10⁻¹⁰ Torr, or not more than 10⁻¹¹ Torr) for long periods of time (e.g. hours, days, weeks, and/or months). In the embodiment shown, vacuum chamber 130 is hermetically sealed. Thus, the HV or UHV pressure in vacuum chamber 130 may be obtained during fabrication and maintained during use of vacuum cell 100. Although not shown in FIGS. 1A-1B, vacuum cell 100 may include an ion or other pump connected or otherwise integrated into vacuum chamber 130. Such a connection may allow for lower pressures to be achieved within vacuum chamber 130 and/or UHV to be maintained for longer times.

Inside vacuum chamber 130 is component 140. Component 140 may be used to perform various functions within vacuum chamber 130. For example, component 140 may be or include an ion trap, neutral-atom trap, photonic assembly, an ion source, or other apparatus attached to vacuum cell 100 (e.g. during fabrication). Further, component 140 may require assembly and/or fabrication. This is indicated by component 140 including parts 142 and 144. Parts 142 and 144 are affixed together via bond 150. Component 140 is attached to vacuum cell 140 by bond 160. Although shown as attached to the bottom of body 110, in some embodiments, component 140 may be attached to another portion of vacuum cell 100. Thus, vacuum cell 100 includes bonds 150 (between portions of component 140), 160 (between component 140 and vacuum cell 100/body 110), and 170 (between body 110 and lid 120). Although one component 140, two portions of the component 142 and 144, and three bonds 140,150, and 160 are shown, in some embodiments, another number of components 140, portions thereof, and/or bonds may be present.

Bond 150 bond 160 and, in some embodiments, bond 170 each has a debonding temperature that is higher than the bonding temperature. As used herein, the bonding temperature is the temperature at which the material(s) used melt and combine such that a bond is formed between the material(s) upon cooling. For example, Au and Sn may be heated to form an Au: Sn bond. The bond remains solid up to the debonding temperature. The debonding temperature is the temperature at which the bond remelts upon reheating. For example, the debonding temperature may be at least ten degrees Celsius higher than the bonding temperature for each of bonds 150, 160, and 170. In some embodiments, the debonding temperature is at least twenty degrees Celsius higher than the bonding temperature for each of bonds 150, 160, and/or 170. In some embodiments, the debonding temperature is at least thirty degrees Celsius higher than the bonding temperature. In some embodiments, the debonding temperature is at least one hundred degrees Celsius higher than the bonding temperature. Other differences between the bonding and debonding temperatures are possible. Bonds 150, 160, and, in some embodiments 170 may be viewed as exhibiting hysteresis in the bonding and debonding temperatures. Stated differently, the temperature at which the materials for bonds 150, 160, and 170 melt depends upon their history. Once materials for bonds 150, 160, and 170 are heat treated to form bonds (e.g. the bonding temperature(s) met or exceeded), a higher debonding temperature is required for the materials to re-melt.

Further, the bonds may be formed in various ways. The surfaces to be bonded may be coated with one or both of the materials used in the bond. For example, gold may be deposited on one surface and tin deposited on another surface. In another example, gold and tin may be deposited on both surfaces to be bonded. In some embodiments, an Au:Sn preform might be used. In such embodiments, an AuSn bonding preform (e.g. with 80/20 ratio) is sandwiched between two gold-coated surfaces. During the bonding process the ratio changes as the Sn migrates into the top/bottom gold layers. More accurately, the alloy changes and migrates between the gold-coated components being bonded. Thus, the bond is formed.

In some embodiments, the bonding temperature is desired to be relatively low, while the debonding temperature is desired to be relatively high. For example, the bonding temperature for one or more of bonds 150, 160 and 170 may be not more than four hundred degrees. In some embodiments, the bonding temperature for one or more of bonds 150, 160 and 170 may be not more than three hundred and fifty hundred degrees Celsius. The bonding temperature for one or more of bonds 150, 160 and 170 may be not more than three hundred degrees Celsius. For example, the bonding and debonding temperature of an Au: Sn bond depends on the ratio of gold to tin. An Au:Sn 80:20 bond may have a bonding temperature of at least 280 degrees Celsius and not more than three hundred and twenty-five degrees Celsius. The debonding temperature may be at least ten to thirty degrees or more higher for such Au: Sn bonds.

Other stoichiometries of Au:Sn and/or other materials may be used for one or more bonds 150, 160, and/or 170 in some embodiments. For example, one or more of bonds 150, 160, and 170 may be an Au:Sn alloy bond, an Au:Ge alloy bond, a Sn:Ag alloy bond, or a Sn—Cu alloy bond. The fractions of the metals used may be selected to achieve the desired bonding and debonding temperatures. In some embodiments, bonds 150, 160, and/or 170 may be formed by other combinations of materials including but not limited to ternary or other alloys and non-metallic bonds. In some embodiments, the alloys formed for bonds 150, 160, and/or 170 are eutectic alloys. In other embodiments, other material(s) forming a bond having a debonding temperature higher than the bonding temperature may be used. For example, transient liquid phase bonding may be used in some embodiments.

Bonds 150, 160, and 170 may also be configured such that the bonding temperatures of some or all bonds are less than the debonding temperatures of other bonds. For example, bond 150 may have a first bonding temperature and a first debonding temperature greater than the first bonding temperature. Bond 160 may have a second bonding temperature that is less than the first debonding temperature. The second bonding temperature for bond 160 may be the same or different than the first bonding temperature of bond 150. Thus, bonds 150, 160, and 170 may use the same or different materials. For example, bonds 150, 160, and 170 may all be Au:Sn bonds having the same or similar stoichiometries (e.g. 80:20 Au:Sn bonds). Alternatively, bond 150 may be an Au:Sn 80:20 bond, while bond(s) 160 and/or 170 may be Au:Ge bonds or Au:Sn bonds having a different stoichiometry. In alternate embodiments, some bond(s) may have bonding temperatures greater than the debonding temperatures of other bonds. However, in such embodiments, the bonds having the higher bonding temperature are desired to be completed first. For example, bond 160 may have a bonding temperature higher than the debonding temperature of bond 170. In such embodiments, bond 160 is formed before bond 170. In such embodiments, the bonds having the higher bonding temperatures may be internal to vacuum chamber 130, while the bond having the lower debonding (and bonding) temperature may be external to the vacuum chamber.

In some embodiments, bonds 150, 160, and 170 are formed by coating portions of opposing surfaces with a component of the bond, placing the opposing, coated surfaces in physical contact, heating the surfaces to at least the bonding temperature, and cooling the surfaces after the bond has been formed. In some embodiments, the bonding temperature is at or near the eutectic point for the alloy being formed. For example, some or all of the bottom surface of part 142 may be coated with gold, while some or all of the top surface of part 144 is coated with tin. In some embodiments, gold and tin may be co-deposited on the bottom surface of part 142 and the top surface of part 144. In some embodiments, the coating may be achieved by sputtering or another deposition method. The geometry of the coating may also be tailored via photolithography or other techniques. Further, the coating provide may be thin. In some embodiments, for example, gold may have a thickness of at least ten nanometer and not more than two micrometers. In some embodiments, the gold (or tin) may have a thickness of not more than one micrometer. In some embodiments, a preform may be used for one or both surfaces. The bottom surface of part 142 and top surface of part 144 (i.e., the gold and tin) are placed into contact and heated to at least the bonding temperature (e.g. at or near three hundred degrees Celsius). In some embodiments, pressure is exerted on parts 142 and/or 144 during the heating process in order to improve bonding. At or above the bonding temperature, the gold and tin flow, forming an alloy. Parts 142 and 144 may then be cooled. In some embodiments, a flow of nitrogen or other passive gas is provided to hasten cooling. Formation of bond 150 is then completed. Subsequent heating of bond 150 debonds the materials at the (higher) debonding temperature instead of the bonding temperature.

Component 140 may then be affixed to vacuum cell 100 using bond 160. Bond 160 may (but need not) be formed in a similar manner to bond 150. Because the bonding temperature for bond 160 is less than the debonding temperature of bond 150, the process of forming bond 160 may not adversely affect bond 150. Bond 170 may (but need not) also be formed in a similar manner to bonds 150 and/or 160. The bonding temperature for bond 170 is less than the debonding temperature(s) of bonds 150 and 160. Thus, bond 170 may be formed without adversely affecting bonds 150 and 160.

Fabrication and operation of vacuum cell 100 may be improved through the use of bonds 150, 160, and 170. Because the bonding temperature(s) of bonds 150, 160, and 170 are less than the debonding temperature(s) component 140 may be fabricated (e.g., bond 150 may be formed) and attached to body 110 via bond 160 without adversely affecting bonding or performance of component 140. Further, vacuum chamber 130 may be hermetically sealed by bond 170 without adversely affecting performance of component 140 or bond 160. The combination of materials used for bonds 150, 160, and/or 170 may be selected such that high-temperature processing, such as bake outs, may be performed as long as the high-temperature processing does not exceed the debonding temperature(s) of bonds 150, 160, and 170. For example, for Au:Sn 80:20 bonds, the bake outs may be performed at temperatures of two hundred to two hundred and fifty degrees Celsius or more. The materials used may form more robust bonds. For example, not only would an Au:Sn 80:20 bond 170 hermetically seal vacuum chamber 130, but is also solid at room temperature (i.e. is less malleable than a material such as indium). Coating of surfaces may also be better controlled for bonds 150, 160, and/or 170 than for preforms. For example, gold and/or tin may be sputter coated or plated. The locations of the gold and/or tin may be lithographically controller. Thus, smaller and/or more complex bonding geometries may be possible than with a preform. Consequently, performance and fabrication of compact vacuum cell 100 may be improved.

FIG. 2 depicts an embodiment of system 200 for fabricating a vacuum cell, such as vacuum cell 100. Although described in the context of vacuum cell 100, system 200 may be used to fabricated other vacuum cells and/or other apparatus. For clarity, not all components of system 200 are shown.

System 200 includes load lock 210 and UHV assembly chamber 220. In operation, components of a vacuum cell may be placed in load lock 210 and moved to UHV assembly chamber 220, which may then be evacuated. Although not shown, UHV assembly chamber 220 may include mechanisms for manipulating the components of the vacuum cell therein. UHV assembly chamber 220 may also include heaters or other mechanisms for controlling temperature. Thus, portions of the vacuum cell may be assembled and bonded. Further, the final sealing of the vacuum cell may take place under UHV. Thus, the presence of bulky valves, pinch-offs, or high-throughput vacuum pumps in the final vacuum cell may be avoided. UHV assembly chamber 220 may also include mechanisms for testing the vacuum cell formed.

For example, parts 142 and 144 of component 140 may be placed in UHV assembly chamber 220. Parts 142 and 144 may have been precoated with the materials used for bond 150. In UHV chamber, parts 142 and 144 may be placed in contact and heated. In some embodiments, the heating is under sufficient pressure to allow for flow of the materials and formation of bond 150. In some embodiments, fabrication of component 140 need not take place in UHV assembly chamber 220. If this fabrication takes place under UHV, body 110 of vacuum cell 100 may then be placed in load lock 210, which is then evacuated. Body 110 may be moved to UHV assembly chamber 220, component 140 placed in chamber 130. Bond 160 may be in an analogous manner to bond 150. Lid 120 may then be placed in load lock 210, which is then evacuated. Lid 120 may be moved to UHV assembly chamber 220 and placed on body 110. Because this occurs in UHV assembly chamber, vacuum chamber 130 is already under UHV (or HV). Bond 170 may then be formed in an analogous manner to bond 150. Thus, vacuum cell 100 having a UHV in vacuum chamber 130 as fabricated may be formed.

In some embodiments, a sealing stage assembly (not shown) may be used to form bonds, such as bonds 150, 160, and/or 170. The sealing stage assembly may be within UHV assembly chamber 220 or, where a UHV is not needed, separate from UHV assembly chamber 220. In such embodiments, the sealing stage assembly may include a mounting platform that has a heating element. In some embodiments, the region of the mounting platform may be brought to vacuum levels below 10⁻⁷ Torr. Components to be sealed may be carried in individual metallic pucks that include alignment features used to align the pucks (and the components therein) with respect to each other. Thus, a well-aligned mate at the bonding interface can be established. In such embodiments, components to be bonded are placed in mated pucks. Some or all of the surface of each component to be bonded may be pre-coated with bonding material(s). For example, one component may be coated with gold, while the other component may include tin pads at regions to be bonded. The mated pucks are loaded on to the sealing stage. The pucks are brought together such that the surfaces of the components to be bonded are brought into contact. While pressure applied between them, the pucks may be heated to just below the final bonding temperature (e.g. at or near 300 degrees Celsius). Due to mostly radiative losses, the heating element typically operates at a much hotter temperature than that measured at the bonding assembly. Once the assembly reaches to within approximately fifteen degrees centigrade of the bonding temperature, a small amount of nitrogen gas (and/or other gas inert with respect to the bonding materials and parts being bonded) may be introduced. The gas may convectively heat the bonding assembly to the final bond temperature. The gas is kept in the chamber for a hold time (e.g. approximately three minutes), after which the chamber is then evacuated at a high rate. Additional nitrogen may be introduced to the chamber to cool the bond assembly at a rapid rate. Utilizing nitrogen for heating and cooling allows the process to quickly bring the assembly to the final bond. In some embodiments, the bonds may be tested within UHV assembly chamber 220 to ensure bonding has been carried out as desired.

Thus, using system 200, vacuum cell 100 may be readily formed. In some embodiments, pinch-offs, valves, and/or other components may not be required to obtain the desired vacuum in vacuum cell 100. Fabrication may also be simplified. Further, because bonds 150, 160, and 170 have the characteristics described herein, vacuum cell 100 may be more robust and have improved performance. Thus, fabrication and operation of vacuum cells may be improved.

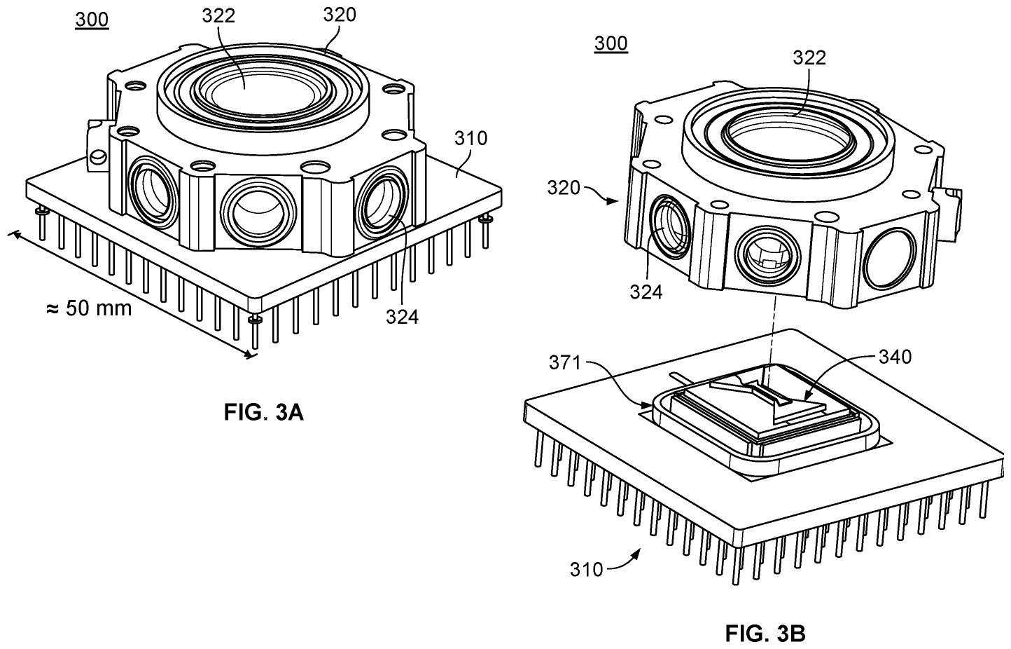

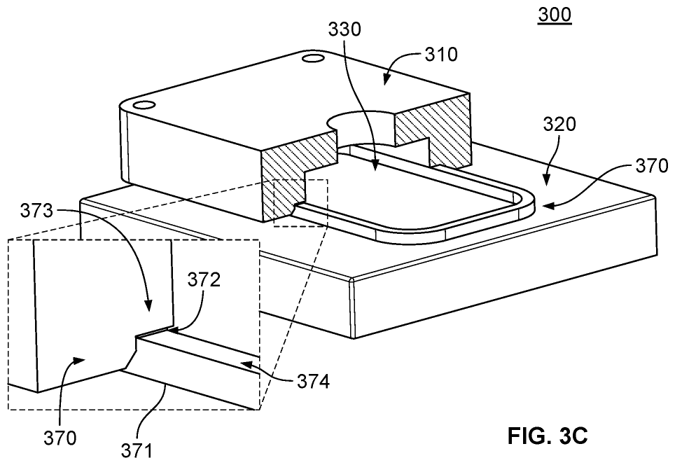

FIGS. 3A-3C are diagrams depicting a perspective view of a portion of one embodiment of vacuum cell 300 that may include multiple bonds. FIG. 3A depicts an assembled view of vacuum cell 300. FIG. 3B depicts an exploded view of vacuum cell 300. FIG. 3C is a cross-sectional perspective view indicating the bonding of a portion of vacuum cell 300. In the embodiment shown, vacuum cell 300 includes an ion trap. For simplicity, ion trap 340 is not shown in FIG. 3C.

Vacuum cell 300 includes body 310 and lid 320, which form vacuum chamber 330 therebetween. Vacuum cell 300 houses component 340, which may be an ion trap. Vacuum cell 300, body 310, lid 320, bond 370, and component 340 are analogous to vacuum cell 100, body 110, lid 120, bond 170, and component 140, respectively. Vacuum cell body 310 is a ceramic pin-grid array (CPGA) in the embodiment shown. In another embodiment, CPGA 310 may be replaced by a machined substrate with welded feedthroughs, a photonics integrated circuit, or by another analogous component. CPGA 310 allows for electrical connection to be provided to ion trap 340. CPGA 310 includes ring frame 371 that may be machined from the substrate or attached to the substate. Ring frame 371 fits into mating groove 373 in vacuum lid 320 where the vacuum seal is made at the interface of each piece. Ring frame 371 and mating groove 373 include materials 372 and 374 used for bond 370. For example, 374 may include gold, while 372 may include tin. Thus, bond 370 may be formed by placing materials 372 and 374 in contact and heating as described in the context of vacuum cell 100 and system 200. Bond 370 thus has a debonding temperature that is higher than the bonding temperature. Further, bond 370 may be a metal alloy bond that is more robust and permanent.

Also shown in FIGS. 3A-3B are view port 322 and optical access 324 (of which only one is labeled). In some embodiments, viewport 322 and optical access 324 are bonded to lid 320 using bonds analogous to bonds 150, 160, 170, and/or 370. Further, component 340 typically includes bonds analogous to bonds 150, 160, 170, and 370. Thus, additional bonds having debonding temperatures higher than bonding temperatures (e.g. at least ten degrees Celsius higher, at least twenty degrees Celsius higher, or more) and which may be formed of alloys such as Au:Sn 80:20 and/or Au:Ge are present in vacuum cell 300.

Vacuum cell 300 may share the benefits of vacuum cell 100. For example, bonds that are hermetic and robust may be used to attach and/or seal portions of vacuum cell 300. Further, bonds may be formed at different times during fabrication of vacuum cell 300 without adversely affecting performance of vacuum cell 300. Moreover, the regions at which bonds are formed may be more finely controlled via placement and/or patterning of the material(s) used in the bond. These benefits may be achieved in a vacuum cell that is compact (e.g. not more than seventy millimeters in length, not more than sixty millimeters in length, or not more than fifty millimeters in length). Consequently, fabrication and performance of vacuum cell 300 may be improved.

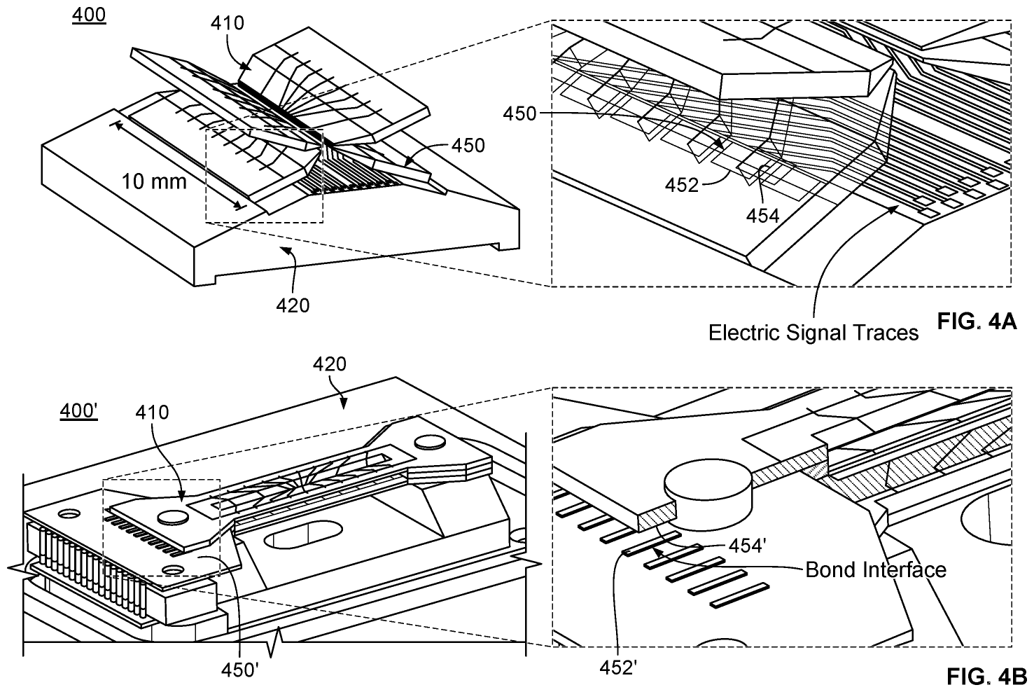

FIGS. 4A-4B are diagrams depicting perspective views of a portion of embodiments of vacuum cells 400 and 400′ including multiple bonds. More specifically, FIGS. 4A and 4B depict angled ion trap 400 and stacked ion trap 400′. Ion traps 400 and 400′ may be used as component 140 and/or 340 in vacuum cell 100 and/or 300, respectively. For simplicity, only some portions of ion traps 400 and 400′ are shown and/or labeled.

Angled ion trap 400 includes bonds 450. Pads 452 and bottom coated surface 454 are used to form bonds 450. Stacked ion trap 400′ includes bonds 450′ formed from pads 452′ and coated bottom surface 454′. Bonds 450 and 450′ are analogous to bonds 150 and/or 160. Thus, bonds 450 and 450′ have a debonding temperature that is higher than the bonding temperature and may be formed by eutectic alloys. Further, pads 452 and 452′ and surfaces 454 and 454′ may be formed via deposition (e.g. sputter deposition and/or plating) and photolithography. Consequently, the location, thickness, and other features of bonds 450 and 450′ may be finely controlled.

Ion traps 400 and 400′ may be used in vacuum cell(s) 100 and/or 300. Thus, bonds 450 and 450′ may be used in connection with bonds 370. Further, ion traps 400 and/or 400′ may be affixed to vacuum cell 100 and/or 300 via bonds analogous to bond 160. As such, multiple bonds having debonding temperatures higher than the bonding temperatures may be used. Such bonds may be formed of the same or different materials. Consequently, vacuum cells employing ion traps 400 and/or 400′ may enjoy the benefits of vacuum cells 100 and/or 300.

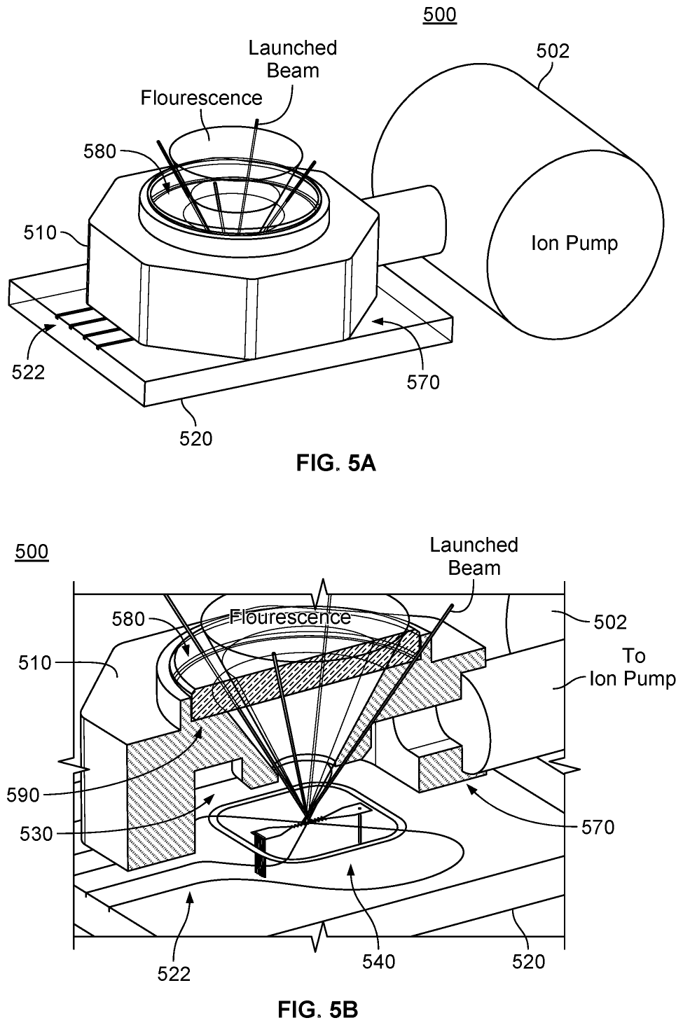

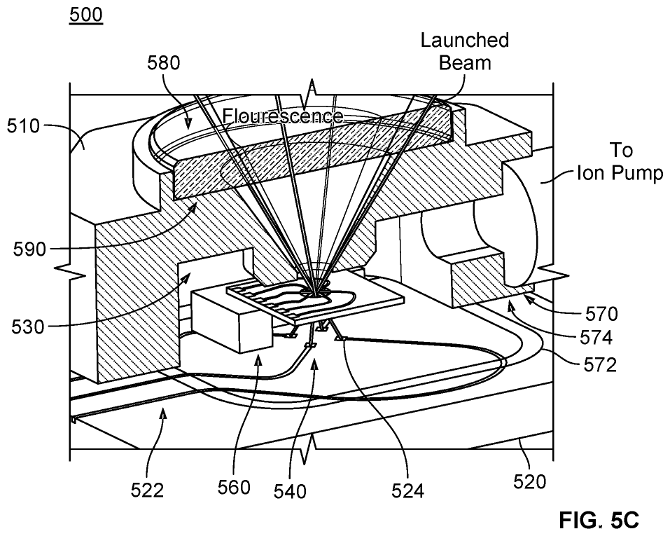

FIGS. 5A-5C are diagrams depicting a perspective view of a portion of an embodiment of vacuum cell 500 including multiple bonds. FIGS. 5A, 5B, and 5C depict an assembled view, a perspective cross-sectional view and a closer perspective cross-sectional view of vacuum cell 500. For clarity, only some portions of vacuum cell 500 are shown.

Vacuum cell 500 includes body 510 and lid 520 that are analogous to body 110 and 310 and lid 120 and 320, respectively. In some embodiments, body 510 is metallic (e.g. Ti), while lid 520 may be a CPGA or photonics substrate (e.g. a photonics integrated circuit). Vacuum chamber 530 is formed between lid 520 and body 510. Also shown is optional ion pump 502 that is coupled to vacuum chamber 530. Component 540 resides in vacuum chamber 530. Component 540 may be an ion trap or other component. Thus, component 540 may include bond(s) analogous to bonds 150 and/or 160.

Lid 520 is bonded to body 510 by bond 570. Bond 570 is analogous to bonds 170 and 370, respectively. Thus, bond 570 has a higher debonding temperature than bonding temperature, provides a robust and hermetic seal, and may be a eutectic alloy. As indicated in FIG. 5C, bond 570 may be formed from materials 572 and 574 placed on opposing surface to be joined via bond 570. Body 520 also includes viewport 580 that is affixed to body 510 via bonds 590. In some embodiments, bond 590 is analogous to bond 570. Thus, bond 590 has a higher debonding temperature than bonding temperature, provides a robust and hermetic seal, may be a eutectic alloy, and may be precisely configured.

Component 540 in vacuum chamber 530 may be an ion trap. Thus, component 540 may be analogous to ion trap(s) 400 and/or 400′. Thus, component 540 may include bonds analogous to bond 150. Component 540 may also be bonded to lid 520 via a bond 560 analogous to bond 160.

In the embodiment shown, lid 520 is an integrated photonics substrate. Consequently, lid 520 includes integrated waveguides 522. Waveguides 522 receive light (e.g. from an optical source external to lid 520) and carry light from the external source to within vacuum chamber 530. For example, waveguides 522 may be optically coupled to optical fiber9s) at the facet of photonics substrate 520. Also shown are grating couplers 524 configured to output light from waveguides 522 to the desired region for atomic trap 540. Thus, launched beams are shown and labeled in FIGS. 5B-5C. Bond 570 between photonics integrated circuit/lid 520 and body 510 is established by a metal-alloy bond 570. Thus, a robust hermetic seal may be formed by bond 570. In forming bond 570, the process and materials are selected such that stress caused by coefficient of thermal expansion (CTE) mismatch between body 510 and photonics substrate 520 does not cause fracturing at the interface or elsewhere in photonics substrate 520.

Vacuum cell 500 may share the benefits of vacuum cells 100 and/or 300. The use of bonds having debonding temperatures higher than bonding temperatures allows for multiple bonds (e.g. bonds within ion trap 540, bond 560, bond 570, and bond 590) within vacuum chamber 530 and between vacuum chamber 530 and the external, ambient environment to be formed. These bonds may be formed of the same or different materials. Use of alloys for bonds described herein allows for precise placement of the materials for the bond and, therefore, control over the geometry of the bonds. Further, the bonds are suitable for use between glass viewports (e.g. port 580) and metal (e.g. body 510), between metals, and/or between photonics substrate (i.e. lid) 520 and metal body 510. Thus, greater flexibility in choice of materials used may be provided. Use of photonics substrate 520 for lid 520 allows for improved coupling of light into vacuum chamber 530 while simplifying design of vacuum cell 500. In addition, vacuum cell 500 may be made more compact and streamlined substantially without sacrificing performance. As such, fabrication and operation of vacuum cell 500 may be improved.

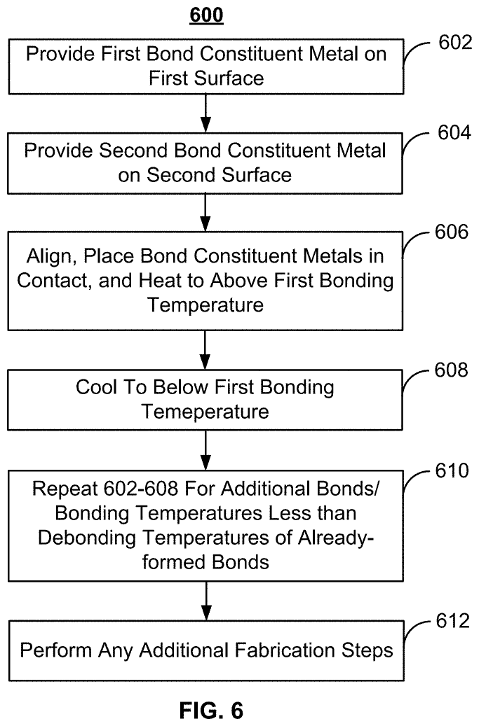

FIG. 6 is a flow chart depicting an embodiment of method 600 for assembling a vacuum cell including multiple bonds. Although shown with various steps, one or more steps may include substeps. In some embodiments, a sealing stage assembly may be used in connection with method 600.

The materials (e.g. metals) used to form the bond are provided on the surfaces to be bonded, at 602 and 604. In some embodiments, 602 and/or 604 include defining the locations of the materials using photolithography, metal preforms, and/or other techniques.

The surfaces to be bonded, and thus the metal constituents of the bond, are aligned, brought into contact, and heated to above the first bonding temperature(s), at 606. The bond is cooled to below the first bonding temperature, at 608. Thus, the desired bond(s) are formed. At 610, 602 through 608 are repeated using temperatures less than the debonding temperature for previously formed bonds. Thus, the metals may melt, flow, and form alloys. Additional processing may be carried out to complete fabrication of the vacuum cell. For example, bake outs, testing of the vacuum cell and/or other steps may be performed.

Using method 600, vacuum cells such as vacuum cells 100, 300, and/or 500 may be formed. Consequently, vacuum cells having improved fabrication and performance may be manufactured.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A vacuum cell, comprising:
a vacuum chamber;
a first bond configured to affix a first portion of the vacuum cell to a second portion of the vacuum cell, the first bond having a first bonding temperature and a first debonding temperature greater than the first bonding temperature; and
a second bond configured to affix a third portion of the vacuum cell to a fourth portion of the vacuum cell, the second bond having a second bonding temperature and a second debonding temperature, the second bonding temperature being less than the first debonding temperature.

2. The vacuum cell of claim 1, wherein the first bond and the second bond are each a metal alloy bond.

3. The vacuum cell of claim 1, wherein the first debonding temperature is at least ten is degrees Celsius greater than the first bonding temperature.

4. The vacuum cell of claim 1, wherein the first bond and the second bond are each selected from a gold-tin alloy bond, a gold-germanium alloy bond, a tin-silver alloy bond, and a tin-copper alloy bond.

5. The vacuum cell of claim 1, wherein at least one of the first bond or the second bond is in the vacuum chamber.

6. The vacuum cell of claim 5, wherein the second bond extends between the vacuum chamber and an exterior surface of the vacuum cell, the exterior surface being configured to be exposed to an ambient environment external to the vacuum chamber.

7. The vacuum cell of claim 5, wherein an ion trap assembly in the vacuum chamber includes the first portion of the vacuum cell and the second portion of the vacuum cell.

8. The vacuum cell of claim 1, wherein the third portion of the vacuum cell includes a metal and the fourth portion of the vacuum cell includes glass such that the second bond is a glass-to-metal bond.

9. The vacuum cell of claim 1, wherein the third portion of the vacuum cell includes a photonic integrated circuit forming a wall of the vacuum cell.

10. The vacuum cell of claim 1, wherein the first bonding temperature and the second bonding temperature do not exceed four hundred degrees Celsius.

11. A vacuum cell, comprising:
a plurality of walls defining a vacuum chamber therein; and
a plurality of bonds within the vacuum chamber, each of the plurality of bonds being a is metal alloy bond having a bonding temperature and a debonding temperature greater than the bonding temperature.

12. The vacuum cell of claim 11, further comprising:
at least one bond affixing a first wall of the plurality of walls to a second wall of the plurality of walls, the at least one having an additional bonding temperature less than the bonding temperature.

13. The vacuum cell of claim 11, wherein at least one of the plurality of walls includes a photonics integrated circuit.

14. A method, comprising:
forming a first bond for a vacuum cell having a vacuum chamber, the first bond being in the vacuum chamber, having a first bonding temperature, and having a first debonding temperature greater than the first bonding temperature; and
forming a second bond having a second bonding temperature after the first bond is formed, the second bonding temperature being less than the first debonding temperature.

15. The method of claim 14, wherein the first bond and the second bond are each a metal alloy bond.

16. The method of claim 15, wherein the first bond includes a first metal and a second metal, and wherein the forming the first bond further includes:
providing the first metal on a first surface of the vacuum cell;
providing the second metal on a second surface of the vacuum cell;
bringing the first metal and the second metal into physical contact; and
heating the first surface and the second surface to at least the first bonding temperature.

17. The method of claim 16, wherein the second bond includes a third metal and a fourth metal, and wherein the forming the first bond further includes:
providing the third metal on a third surface of the vacuum cell;
providing the fourth metal on a fourth surface of the vacuum cell;
bringing the third metal and the fourth metal into physical contact; and
heating the first surface and the second surface to at least the second bonding temperature and less than the first debonding temperature.

18. The method of claim 16, wherein the providing the first metal further includes:
depositing the first metal on the first surface

19. The method of claim 14, wherein the first bond bonds a metal portion of the vacuum cell to a glass portion of the vacuum cell such that the first bond is a glass-to-metal bond.

20. The method of claim 14, wherein the first bond bonds a photonic integrated circuit forming a wall of the vacuum cell to a portion of the vacuum cell.
